(19) United States
(12) Patent Application Publication
(10) Pub. No.: US 2026/0053005 A1
(43) Pub. Date: Feb. 19, 2026

(54) SEMICONDUCTOR DEVICES, LEADFRAMES, SYSTEMS AND ASSOCIATED MANUFACTURING METHODS

(71) Applicant: Infineon Technologies AG, Neubiberg (DE)

(72) Inventors: Chwee Pang TOMMY KHOO, Melaka (MY); Sanjay Kumar MURUGAN, Melaka (MY); Ralf OTREMBA, Kaufbeuren (DE); Zen Yin LIM, Melaka (MY); Dennis VILLAREAL, Melaka (MY); Joo Teng TEOH, Melaka (MY)

(73) Assignee: Infineon Technologies AG, Neubiberg (DE)

(21) Appl. No.: 19/269,839

(22) Filed: Jul. 15, 2025

(30) Foreign Application Priority Data
Aug. 13, 2024 (DE) 10 2024 123 057.6
May 22, 2025 (DE) 10 2025 120 082.3

(51) Int. Cl. H01L 23/495; H01L 23/00; H01L 23/31

(52) U.S. Cl. CPC H01L 23/49503; H01L 23/3107; H01L 23/49517; H01L 23/49562; H01L 23/49575; H01L 24/48; H01L 2224/48245

(57) ABSTRACT

A semiconductor device and method is disclosed. In one example, the semiconductor device includes a first diepad including a first mounting surface and a first elevated portion elevated with respect to the first mounting surface. A first semiconductor chip is mounted on the first mounting surface. The semiconductor device further includes a second diepad including a second mounting surface. A second semiconductor chip is mounted on the second mounting surface and includes an electrical contact arranged on a top surface of the second semiconductor chip facing away from the second mounting surface. The semiconductor device further includes a first electrical connection element electrically connecting the electrical contact of the second semiconductor chip and the first elevated portion of the first diepad.

### CROSS-REFERENCE TO RELATED APPLICATIONS

This Utility Patent Application claims priority to German Patent Application No. 10 2024 123 057.6 filed Aug. 13, 2024, and Germany Priority Application No. 10 2025 120 082.3 filed May 22, 2025, both of which are incorporated herein by reference.

### TECHNICAL FIELD

The present disclosure relates to semiconductor devices, leadframes, systems and associated manufacturing methods.

### BACKGROUND

The development of semiconductor devices is moving towards ever smaller dimensions. In this context, various problems may arise due to the resulting lack of space in the semiconductor devices. For example, there may be insufficient space for properly mounting semiconductor chips on diepads or effectively using bonding tools in the fabrication of the semiconductor devices. In addition, due to lack of space mounted semiconductor chips may overhang diepads or occurring solder bleed may cause damage.

In view of the above, it may be desirable to provide semiconductor devices of smaller size, while at least partially addressing the above identified issues. In addition, it may be desirable to provide simple and cost efficient methods for the fabrication of such semiconductor devices.

### SUMMARY

An aspect of the present disclosure relates to a semiconductor device. The semiconductor device comprises a first diepad comprising a first mounting surface and a first elevated portion elevated with respect to the first mounting surface. The semiconductor device further comprises a first semiconductor chip mounted on the first mounting surface. The semiconductor device further comprises a second diepad comprising a second mounting surface. The semiconductor device further comprises a second semiconductor chip mounted on the second mounting surface and comprising an electrical contact arranged on a top surface of the second semiconductor chip facing away from the second mounting surface. The semiconductor device further comprises a first electrical connection element electrically connecting the electrical contact of the second semiconductor chip and the first elevated portion of the first diepad.

A further aspect of the present disclosure relates to a method for manufacturing a semiconductor device. The method comprises a step of providing a first diepad comprising a first mounting surface and a first elevated portion elevated with respect to the first mounting surface. The method further comprises a step of mounting a first semiconductor chip on the first mounting surface. The method further comprises a step of providing a second diepad comprising a second mounting surface. The method further comprises a step of mounting a second semiconductor chip on the second mounting surface, wherein the second semiconductor chip comprises an electrical contact arranged on a top surface of the second semiconductor chip facing away from the second mounting surface. The method further comprises a step of electrically connecting the electrical contact of the second semiconductor chip and the first elevated portion of the first diepad by a first electrical connection element.

A further aspect of the present disclosure relates to a leadframe. The leadframe comprises a first diepad comprising a first mounting surface and a first elevated portion elevated with respect to the first mounting surface. The leadframe further comprises a second diepad comprising a second mounting surface. The first elevated portion is arranged at a periphery of the first mounting surface opposite the second diepad.

### BRIEF DESCRIPTION OF THE DRAWINGS

Methods and devices in accordance with the disclosure are described in more detail below based on the drawings. The elements of the drawings are not necessarily to scale relative to each other. Similar reference numerals may designate corresponding similar parts. The technical features of the various illustrated examples may be combined unless they exclude each other and/or can be selectively omitted if not described to be necessarily required.

FIG. 1A and FIG. 1B schematically illustrating a top view and a perspective view of a leadframe 100 in accordance with the disclosure.

FIG. 2A and FIG. 2B schematically illustrating a perspective view and a sectional side view of a semiconductor device 200 in accordance with the disclosure.

FIG. 3A to FIG. 3C schematically illustrating a perspective view, a top view and a sectional side view of a semiconductor device 300 in accordance with the disclosure.

FIG. 4 schematically illustrates a sectional side view of a semiconductor device 400 in accordance with the disclosure.

FIG. 5 schematically illustrates a sectional side view of a semiconductor device 500 in accordance with the disclosure.

FIG. 6A and FIG. 6B schematically illustrating a top view and a sectional side view of a semiconductor device 600 in accordance with the disclosure.

FIG. 7 schematically illustrates a sectional side view of a semiconductor device 700 in accordance with the disclosure.

FIG. 8 illustrates a circuit diagram of a half bridge circuit 800.

FIG. 9 schematically illustrates a top view of a system 900 in accordance with the disclosure.

FIG. 10 schematically illustrates a perspective view of a leadframe 1000 in accordance with the disclosure.

FIG. 11 schematically illustrates a perspective view of a leadframe 1100 in accordance with the disclosure.

FIG. 12 illustrates a flowchart of a method for manufacturing a semiconductor device in accordance with the disclosure.

FIG. 13 illustrates an exemplary method step of a method for manufacturing a semiconductor device in accordance with the disclosure.

FIG. 14 illustrates an exemplary method step of a method for manufacturing a semiconductor device in accordance with the disclosure.

FIG. 15A and FIG. 15B schematically illustrating a perspective bottom view and a sectional side view of a semiconductor device 1500 in accordance with the disclosure.

FIG. 16A and FIG. 16B schematically illustrating a perspective bottom view and a sectional side view of a semiconductor device 1500 in accordance with the disclosure.

### DETAILED DESCRIPTION

In the following detailed description, reference is made to the accompanying drawings, in which are shown by way of illustration specific aspects in which the disclosure may be practiced. In this regard, directional terminology, such as “top”, “bottom”, “front”, “back”, etc. may be used with reference to the orientation of the figures being described. Since components of described devices may be positioned in a number of different orientations, the directional terminology may be used for purposes of illustration and is in no way limiting. Other aspects may be utilized and structural or logical changes may be made without departing from the concept of the present disclosure. Hence, the following detailed description is not to be taken in a limiting sense, and the concept of the present disclosure is defined by the appended claims.

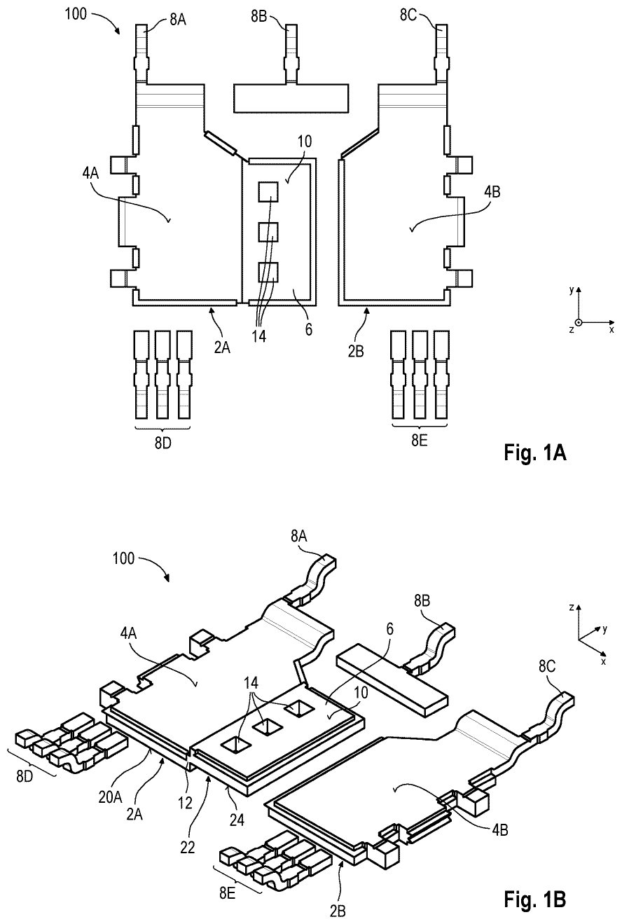

Referring now to FIG. 1A and FIG. 1B, different views of a leadframe 100 in accordance with the disclosure are shown. The leadframe 100 may include a first diepad 2A having a first mounting surface 4A and a second diepad 2B having a second mounting surface 4B. The first diepad 2A may include an elevated portion 6 elevated with respect to the first mounting surface 4A. The leadframe 100 may further include a plurality of leads (or lead fingers or pins) 8 which may be arranged at a periphery of the diepads 2A and 2B.

The leadframe 100 (i.e. the diepads 2A, 2B and the leads 8) may include or may be made of a metal or a metal alloy. For example, the leadframe 100 may include a core material including at least one of copper, copper alloy, aluminum, aluminum alloy, or the like. Optionally, the leadframe 100 may be plated with at least one plating material, which may, for example, include at least one of nickel, nickel-phosphorous, nickel-nickel-phosphorous, copper, silver, or the like. The plating material may cover the entire leadframe 100 (or its core material) or only selected portions of it. It is to be understood that the core material and the plating material of the leadframe 100 may depend on a type of semiconductor chip that is to be mounted on the diepads 2A, 2B and/or a material of an electrical connection element (e.g. wire, ribbon, clip, or the like) that is to be connected to the diepads 2A, 2B and/or the leads 8.

In an example, the elevated portion 6 may be plated with a first plating material configured to provide a bondability of the elevated portion 6 for an electrical connection element that is to be connected to the elevated portion 6. In a first case of an electrical connection element implemented as a copper and/or gold wire, the first plating material may include or correspond to a stripe or spot silver plating. In a second case of an electrical connection element implemented as an aluminum wire, the first plating material may include or may correspond to a stripe or spot NiNiP plating. In a third case of an electrical connection element implemented as a copper wire, the first plating material may include or may correspond to at least one of a copper stripe plating or a rough copper plating.

Additionally, or alternatively, the first mounting surface 4A of the first diepad 2A may be plated with a second plating material, which may be different from the first plating material. In particular, the second plating material may provide a bondability of the first mounting surface 4A for a semiconductor chip that is to be attached to the first mounting surface 4A. In general, a die attach material may include at least one of a diffusion solder material, a soft solder material (which may be applied by dispensing and/or printing), a DAF-(Die Attach Film)-tape or a material suitable for a welding process. In one particular example, a semiconductor chip may be soldered to the first mounting surface 4A by a solder material. It is to be understood that previous comments may similarly hold true for a plating material applied to the second mounting surface 4B of the second diepad 2B.

The elevated portion 6 of the first diepad 2A may be arranged at a periphery of the first mounting surface 4A opposite the second diepad 2B. In the exemplary top view of FIG. 1A, the elevated portion 6 may be arranged along the right side of the first mounting surface 4A extending in the y-direction and facing the second diepad 2B. In the shown case, the elevated portion 6 may extend along the entire right side of the mounting surface 4A. In further examples, the elevated portion 6 may only extend along a portion of the right side of the mounting surface 4A, i.e. a dimension of the elevated portion 6 measured in the y-direction may be reduced.

A top surface 10 of the elevated portion 6 may be substantially parallel to the first mounting surface 4A. Both surfaces may exemplarily extend in the x-y-plane. In the illustrated example, a surface area of the top surface 10 of the elevated portion 6 may be smaller than a surface area of the first mounting surface 4A. However, in further examples, a surface area of the top surface 10 of the elevated portion 6 may be greater than or equal to a surface area of the first mounting surface 4A.

The first mounting surface 4A of the first diepad 2A and the elevated portion 6 may form at least one step at a periphery of the first mounting surface 4A. In the illustrated example, a single formed step may be rectangular, i.e. a portion 12 of the first diepad 2A connecting the first mounting surface 4A and the elevated portion 6 may be substantially perpendicular to the first mounting surface 4A and to the top surface 10 of the elevated portion 6. An angle between the first mounting surface 4A and the portion 12 may be about 90 degrees. In further examples, this angle may differ and may be smaller or greater than 90 degrees.

A bottom surface 20A of the first diepad 2A opposite the first mounting surface 4A may include a recess 22 opposite the top surface 10 of the elevated portion 6. The recess 22 may result from the step formed by the first mounting surface 4A and the elevated portion 6. In this context, the portion of the first diepad 2A including the first mounting surface 4A and the portion of the first diepad 2A including the elevated portion 6 may have a similar (or equal) thickness when measured in the z-direction. However, in further examples, the bottom surface 20A of the first diepad 2A opposite the first mounting surface 4A and a bottom surface 24 of the elevated portion 6 opposite the top surface 10 may be coplanar, i.e. arranged in a common plane. In such case, a thickness of the portion of the first diepad 2A including the first mounting surface 4A may be smaller than a thickness of the portion of the first diepad 2A including the elevated portion 6 when measured in the z-direction.

The elevated portion 6 may optionally include at least one opening 14 extending through the elevated portion 6 from its top surface 10 to its bottom surface 24. In the illustrated example, an exemplary number of three openings 14 are shown which may differ in further examples. As will become apparent later on, an encapsulation material may extend through the at least one opening 14 such than an interlocking feature may be provided.

The leads 8 may e.g. be arranged at opposite sides of the leadframe 100. In the illustrated example, the leadframe 100 may include three single leads 8A to 8C arranged at a first side of the leadframe 100 as well as a first plurality of leads 8D and a second plurality of leads 8E arranged at an opposing second side of the leadframe 100. It is to be understood that the number of leads 8 may differ in further examples and may particularly depend on a specific design of a semiconductor device including the leadframe 100. Some of the leads 8 may be connected to the diepads 2A, 2B, while other ones of the leads 8 may be separated from the diepads 2A, 2B.

In the example of FIG. 1A and FIG. 1B, only a single leadframe 100 is shown for illustrative purposes. It is to be understood that fabricating semiconductor devices in a batch process may be based on a leadframe panel (or a leadframe strip) including one or multiple rows of leadframes, wherein the number of leadframes included in a row may be up to a few dozens or even more. For example, the individual leadframes of a leadframe panel may be mechanically connected by tie bars. After performing steps of the batch process, the processed arrangement including the leadframe panel may be separated into multiple semiconductor devices (or semiconductor packages) by cutting the tie bars.

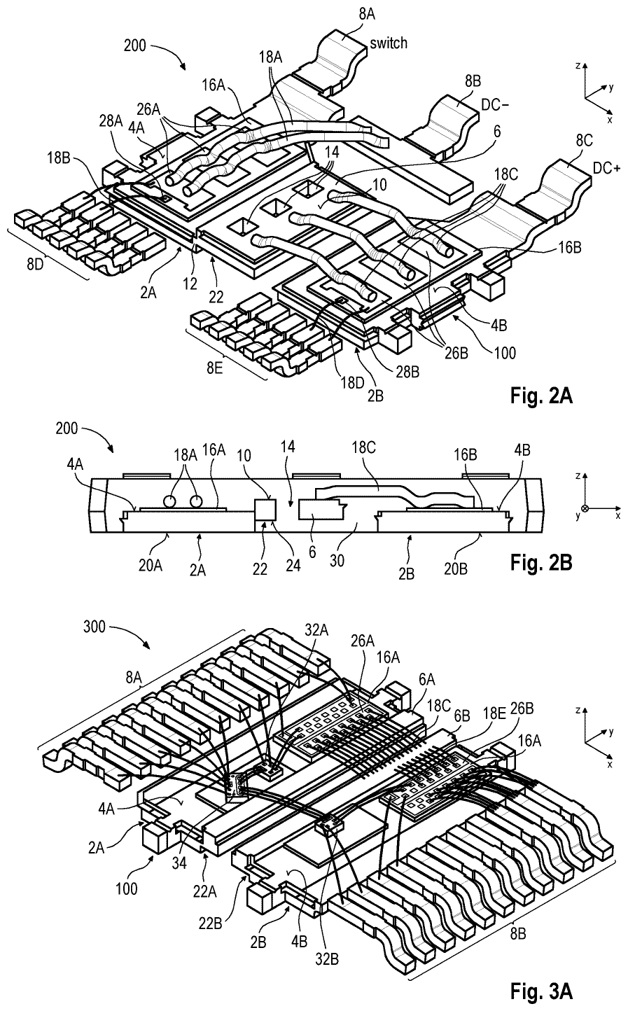

Referring now to FIG. 2A and FIG. 2B, different views of a semiconductor device 200 in accordance with the disclosure are shown. FIG. 2B shows a sectional side view of the semiconductor device 200 along a sectional plane, wherein not all components illustrated in the perspective view of FIG. 2A may be visible in FIG. 2B. The semiconductor device 200 may include a leadframe 100, which may include some or all features of the leadframe 100 of FIG. 1A and FIG. 1B to which reference is made herewith. The semiconductor device 200 may further include a first semiconductor chip 16A mounted on the first mounting surface 4A of the first diepad 2A and a second semiconductor chip 16B mounted on the second mounting surface 4B of the second diepad 2B. In addition, the semiconductor device 200 may include a plurality of electrical connection elements 18 described later on.

In general, the semiconductor chips described herein may be manufactured from an elemental semiconductor material (e.g. Si) or from a wide band gap semiconductor material or a compound semiconductor material (e.g. SiC, GaN, SiGe, GaAs). The semiconductor chips may be of arbitrary types and may include integrated circuits with active electronic components and/or passive electronic components. The integrated circuits may be designed as logic integrated circuits, analog integrated circuits, mixed signal integrated circuits, power integrated circuits, memory circuits, integrated passives, etc. Note that, throughout this description, the terms “chip”, “semiconductor chip”, “die”, “semiconductor die” may be used interchangeably.

In particular, the semiconductor chips 16A, 16B may be power semiconductor chips. In this context, the term “power semiconductor chip” may refer to a semiconductor chip providing at least one of high voltage blocking or high current-carrying capabilities. A power semiconductor chip may be configured for high currents having a maximum current value of a few Amperes, such as e.g. 10 A, or a maximum current value of up to or exceeding 100 A. Similarly, voltages associated with such current values may have values of a few Volts to a few tens or hundreds or even thousands of Volts, such as e.g. about 1200V, about 1600V, about 2400V, or the like. Power semiconductor chips may be used in any kind of power application like e.g. MOSFETs (Metal Oxide Semiconductor Field Effect Transistors), half bridge circuits, power modules including a gate driver, etc. For example, power semiconductor chips may include or may be part of a power device like e.g. a power MOSFET, an LV (low voltage) power MOSFET, a power IGBT (Insulated Gate Bipolar Transistor), a power diode, a superjunction power MOSFET, or the like.

The first semiconductor chip 16A may include at least one first electrical contact 26A and at least one second electrical contact 28A arranged on the top surface of the first semiconductor chip 16A facing away from the first mounting surface 4A. In addition, the first semiconductor chip 16A may include at least one third electrical contact (not shown) arranged on the bottom surface of the first semiconductor chip 16A facing the first mounting surface 4A. In the illustrated example, the first semiconductor chip 16A may include or may correspond to a vertical power chip. The vertical power chip may be manufactured from an elemental semiconductor material (in particular silicon) or from a wide band gap semiconductor material or a compound semiconductor material (in particular SiC).

In the illustrated example, the first semiconductor chip 16A may correspond to a power transistor chip, such as a power MOSFET chip or a power IGBT chip. In case of a power MOSFET, the at least one first electrical contact 26A may be a source contact, the at least one second electrical contact 28A may be a gate contact, and the at least one third electrical contact may be a drain contact of the power MOSFET. In case of a power IGBT, the discussed electrical contacts may represent a base, a collector and an emitter of the power IGBT. The second semiconductor chip 16B may be at least partially similar to the first semiconductor chip 16A and may similarly include electrical contacts 26B, 28B arranged on its top surface and on its bottom surface as previously described. In one specific, but non-limiting example, each of the semiconductor chips 16A and 16B may be based on or include silicon carbide.

The plurality of electrical connection elements 18 of the semiconductor device 200 may be configured to electrically interconnect previously described device components as shown in FIG. 2A and FIG. 2B and described in the following. At least one first electrical connection element 18A may electrically connect the lead 8B and the first electrical contact 26A of the first semiconductor chip 16A. In the illustrated example, the first electrical connection element 18A may include an exemplary number of two thick wires.

At least one second electrical connection element 18B may electrically connect at least one of the leads 8D with the second electrical contact 28A of the first semiconductor chip 16A. In the illustrated example, the second electrical connection element 18B may exemplarily include a single thin wire. The third electrical contact arranged at the bottom surface of the first semiconductor chip 16A may be electrically connected to the lead 8A via the first diepad 2A. In this context, the lead 8A and the first diepad 2A may be formed as one single piece. Due to the described electrical interconnections, the electrical contacts of the first semiconductor chip 16A may be electrically accessible via the leads 8A, 8B and 8D. In case of a power MOSFET chip, the lead 8A may be referred to as drain lead, the lead 8B may be referred to as source lead and the lead 8D may be referred to as gate lead. As will be discussed later on, in case of the semiconductor device 200 including a half bridge circuit, the lead 8A may represent a switch node of the half bridge circuit.

At least one third electrical connection element 18C may electrically connect the electrical contact 26B of the second semiconductor chip 16B and the top surface 10 of the first elevated portion 6 of the first diepad 2A. In the illustrated example, the third electrical connection element 18B may include an exemplary number of three thick wires. The electrical contact of the first semiconductor chip 16A arranged on the bottom surface of the first semiconductor chip 16A may be electrically connected to the electrical contact 26B of the second semiconductor chip 16B via the first mounting surface 4A of the first diepad 2A, the first elevated portion 6 and the third electrical connection element 18C. In case of two power MOSFET chips, the third electrical connection element 18C may connect a drain contact of the first semiconductor chip 16A and a source contact of the second semiconductor chip 16B. In this context, the first semiconductor chip 16A and the second semiconductor chip 16B may form part of a low side switch and a high side switch of a half bridge circuit. In particular, the first semiconductor chip 16A may form part of a low side switch, while the second semiconductor chip 16B may form part of a high side switch.

At least one fourth electrical connection element 18D may electrically connect at least one of the leads 8E with the second electrical contact 28B of the second semiconductor chip 16B. The third electrical contact arranged on the bottom surface of the second semiconductor chip 16B may be electrically connected to the lead 8C via the second diepad 2B. In this regard, the lead 8C and the second diepad 2B may be formed as one single piece. Due to the described electrical interconnections, the electrical contacts of the second semiconductor chip 16B may be electrically accessible via the leads 8C and 8E. The lead 8C may be referred to as drain lead, and the leads 8E may be referred to as gate leads.

The semiconductor device 200 may include an encapsulation material 30, which is only shown in the sectional side view of FIG. 2B, but not in the perspective view of FIG. 2A, in order to not obscure device components in FIG. 2A. The encapsulation material 30 may include or may be made of at least one of an epoxy, a filled epoxy, a glass fiber filled epoxy, an imide, a thermoplast, a thermoset polymer, a polymer blend, a laminate, a mold compound, or the like. Various techniques may be used for encapsulating components in the encapsulation material 30, for example at least one of compression molding, injection molding, powder molding, liquid molding, map molding, laminating, or the like.

The encapsulation material 30 may at least partially encapsulate the first diepad 2A, the second diepad 2B, the first semiconductor chip 16A and the second semiconductor chip 16B. The leads 8 of the semiconductor device 200 may at least partially protrude out of the encapsulation material 30 such that electrical contacts of the semiconductor chips 16A, 16B connected to corresponding leads 8 may be accessible from outside of the encapsulation material 30. The semiconductor device 200 may thus be referred to as a leaded package (in contrast to a leadless package). In a similar fashion, at least a part of the bottom surface 20A of the first diepad 2A and the bottom surface 20B of the second diepad 2B may be uncovered by the encapsulation material 30 such that electrical contacts arranged on the bottom surfaces of the semiconductor chips 16A, 16B and connected to the diepads 2A, 2B may be accessible from outside of the encapsulation material 30. In the illustrated example, the bottom surface 24 of the elevated portion 6 may be at least partially covered by the encapsulation material 30. However, in further examples, the bottom surface 24 of the elevated portion 6 may be at least partially uncovered by the encapsulation material 30. The encapsulation material 30 may at least partially extend through the openings 14, wherein an interlocking between the encapsulation material 30 and the first diepad 2A may be provided. This way, a detachment of the encapsulation material 30 may be avoided.

In general, the leads 8A to 8C may be referred to as power leads of the semiconductor device 200, while the leads 8D and 8E may be referred to as logical leads of the semiconductor device 200. A power lead may be associated with and/or may be configured to handle a high current and/or a high voltage that is associated with the function of the connected semiconductor chip. That is, a power lead may be associated with a high power domain of the device. For example, a drain lead or a source lead connected to a power MOSFET may be referred to as power lead. A logical lead may be associated with and/or may be configured to handle control signals, communication signals, status information signals, or the like, associated with the connected semiconductor chip. For example, a gate lead connected to a power MOSFET may be referred to as logical lead. In general, logical leads may operate at lower power levels (e.g. typically standard digital or analog signal levels) compared to the power leads. A logical lead may be associated with a low power domain of the device.

The power terminals of the first semiconductor chip 16A and of the second semiconductor chip 16B may be exclusively electrically connected to leads arranged at one side of the semiconductor device 200. In the shown case, the source and drain terminals of the semiconductor chips 16A, 16B may be connected to the power leads 8A to 8C arranged at the right side of the semiconductor device 200. The logical terminals of the first semiconductor chip 16A and of the second semiconductor chip 16B may be exclusively electrically connected to leads arranged at an opposite side of the semiconductor device 200. In the shown case, the gate terminals of the semiconductor chips 16A, 16B may be connected to the logical leads 8D, 8E arranged at the left side of the semiconductor device 200. As a result, the power leads and the logical leads may be arranged on opposite sides of the semiconductor device 200, which may provide for an improved electrical isolation between a high power domain and a low power domain of the semiconductor device 200.

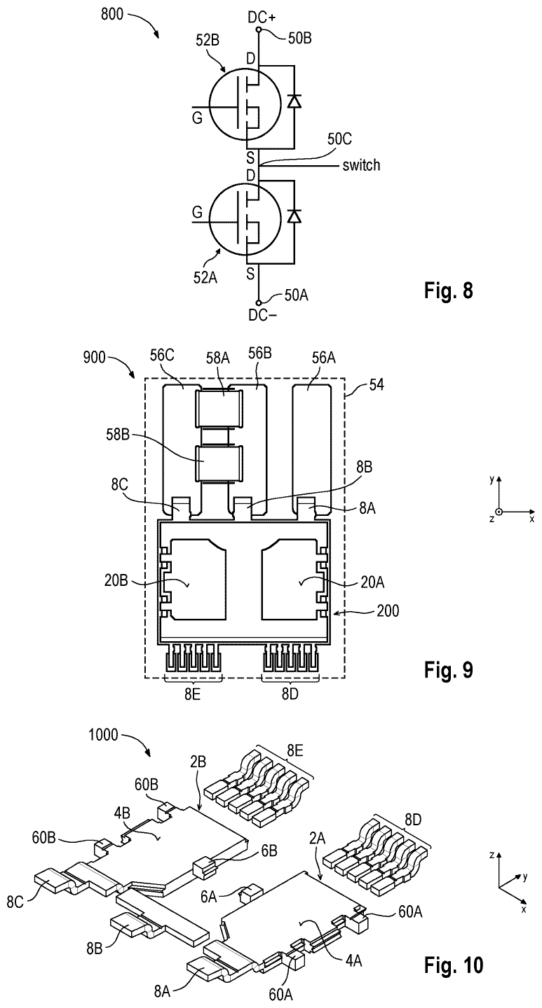

In the illustrated example, the semiconductor device 200 may include a half bridge circuit. An exemplary circuit diagram of a half bridge circuit 800 is shown in FIG. 8. The half bridge circuit 800 may be arranged between two terminals 50A and 50B. The half bridge circuit 800 may include two switches 52A and 52B connected in series. The switch 52A may be a low side switch of the half bridge circuit, while the switch 52B may be a high side switch of the half bridge circuit. Constant electrical potentials may be applied to the terminals 50A and 50B. For example, a high potential, such as about 10V, about 50V, about 100V, about 200V, about 500V or about 1000V or any other potential, may be applied to the terminal 50B and a low electrical potential, for example about 0V, may be applied to the terminal 50A. The switches 52A and 52B may be switched at frequencies in the range from about 1 kHz to about 100 MHz, but the switching frequencies may also be outside this range. This means that a varying electrical potential may be applied to a terminal 50C arranged between the switches 52A and 52B during an operation of the half bridge circuit 800. The terminal 50C may be referred to as switch node. The potential of the terminal 50C may vary in the range between the low and the high electrical potential.

For example, the half bridge circuit 800 may be implemented in electronic circuits for converting DC voltages, so-called DC-DC converters. DC-DC converters may be used to convert a DC input voltage provided by a battery or a rechargeable battery into a DC output voltage matched to the demand of electronic circuits connected downstream. DC-DC converters may be embodied as e.g. step-down converters, in which the output voltage may be less than the input voltage, or as e.g. step-up converters, in which the output voltage may be greater than the input voltage. Frequencies of several MHz or higher may be applied to DC-DC converters. Furthermore, currents of up to about 50 A or even higher may flow through the DC-DC converters.

Referring back to the example of FIG. 2A, the first semiconductor chip 16A and the second semiconductor chip 16B may form part of the low side switch 52A and the high side switch 52B of the half bridge circuit. More particular, the first semiconductor chip 16A may form part of the low side switch 52A, while the second semiconductor chip 16B may form part of the high side switch 52B.

The power lead 8B may be electrically connected to a power terminal of the first semiconductor chip 16A, while the power lead 8C may be electrically connected to a power terminal of the second semiconductor chip 16B. In the illustrated example, the power lead 8B may be electrically connected to the source of the first semiconductor chip 16A (or to the low side switch), while the power lead 8C may be electrically connected to the drain of the second semiconductor chip 16B (or to the high side switch). It is to be noted that the power lead 8B and the power lead 8C may be arranged at a same first side of semiconductor device 200. Note further that the power lead 8B and the power lead 8C may be arranged directly next to each other.

The power lead 8C may be configured to receive a supply power and/or a supply voltage. In the illustrated example, the power lead 8C may be a DC+ (or Vcc) terminal of the half bridge circuit. The power lead 8B may be configured to output an electric current. In the illustrated example, the power lead 8B may be a DC− terminal of the half bridge circuit. For example, the power lead 8B may connect to ground.

The power lead 8A may be electrically connected to the first semiconductor chip 16A and to the second semiconductor chip 16B. In the illustrated example, the power lead 8A may be electrically connected to the drain of the first semiconductor chip 16A and to the source of the second semiconductor chip 16B. The power lead 8A may be electrically connected to the switch node of the half bridge circuit (see 50C in FIG. 8). The power lead 8A may be configured to output a power and/or a signal. It is to be noted that the power lead 8A may be arranged at the same side of the semiconductor device 200 next to the power leads 8B and 8C. That is, the DC terminals DC+ and DC− as well as the switch node of the half bridge circuit are arranged all at a same side of the semiconductor device 200. In particular, the DC+ terminal may be arranged directly next to the DC− terminal.

Semiconductor devices in accordance with the disclosure, such as the semiconductor device 200 of FIG. 2A and FIG. 2B, may be part of a system. In this connection, it is now referred to the example of FIG. 9, which schematically illustrates a top view of a system 900 in accordance with the disclosure. The system 900 may include a printed circuit board (PCB) 54 on which the semiconductor device 200 may be arranged. It is to be noted that only a portion of the PCB 54 is shown and that an arbitrary number of additional components may be arranged on the PCB 54. In the illustrated example, the surfaces 20A and 20B of the diepads 2A and 2B may face away from the mounting surface of the PCB 54. The leads 8A to 8E of the semiconductor device 200 may be connected electrically and mechanically to conductive traces 56 of the PCB 54. In this regard, the power lead 8B may be electrically connected to a first conductive trace 56B of the PCB 54, while the power lead 8C may be electrically connected to a second conductive trace 56C of the PCB 54.

The system 900 may further include at least one capacitor 58 electrically connected between the first conductive trace 56B and the second conductive trace 56C. In the illustrated example, an exemplary number of two capacitors 58A, 58B may be connected between the conductive traces 56B, 56B and thus between the two DC terminals DC+ and DC− of the semiconductor device 200. The use of capacitors connected between the DC terminals DC+ and DC− may be particularly beneficial for high frequency switching applications utilizing a half bridge configuration as previously described. It is to be noted that the simple and efficient arrangement of the capacitor(s) 58 between the DC terminals is facilitated and made possible due to the arrangement of the DC leads 8B and 8C at the same side of the semiconductor device 200 adjacent to each other. In contrast to this, conventional semiconductor devices may have DC terminals arranged on opposite sides of the respective device such that a reasonable arrangement of a capacitor may become difficult. The semiconductor device 200 and associated systems may thus outperform conventional solutions.

In addition, the semiconductor device 200 may outperform conventional semiconductor devices in various other ways. In this context, the following comments should not be regarded as exhaustive. It is to be understood that the following comments may also hold true for all further semiconductor devices in accordance with the disclosure.

Compared to conventional semiconductor devices, the semiconductor device 200 may provide an increased first mounting surface 4A, i.e. larger semiconductor chips may be mounted on the first diepad 2A. As shown in the example of FIG. 2A, the electrical connection elements 18C may be connected to the top surface 10 of the elevated portion 6. In contrast to this, conventional semiconductor devices may not include the elevated portion 6 such that the electrical connection elements 8C may need to be connected to the first mounting surface 4A instead. Such connection may naturally require a portion of the first mounting surface 4A such that the available area for mounting the semiconductor chip 16A on the first mounting surface 4A may be reduced. For example, this may result in the mounted semiconductor chip 16A protruding beyond the contour of the first diepad 2A in an undesired manner.

Compared to conventional semiconductor devices, the semiconductor device 200 may avoid cutting tool marks on the first semiconductor chip 16A. In conventional semiconductor devices not including the elevated portion 6, the electrical connection elements 18C may need to be connected to the first mounting surface 4A. Here, a cutting tool may hit the first semiconductor chip 16A when cutting the electrical connection elements 18C due to space constraints. As a result, undesired cutting tool marks may remain on the first semiconductor chip 16A. In contrast to this, in the semiconductor device 200, the electrical connection elements 18C may be bonded to the elevated portion 6 so that a mechanical contact between the first semiconductor chip 16A and the cutting tool may be avoided.

Furthermore, the elevated portion 6 of the first diepad 2A may be configured as a solder bleed barrier for a solder material that is used for attaching the first semiconductor chip 16A to the first mounting surface 4A. In this context, a distance between the first semiconductor chip 16A and the elevated portion 6 may be smaller than a distance between the first semiconductor chip 16A and an edge of the first diepad 2A opposite an edge of the elevated portion 6. Due to the elevated portion 6 being configured as a solder bleed barrier, the first semiconductor chip 16A may be arranged closer to the elevated portion 6 such that a distance to the opposite edge of the first diepad 2A may be increased. This may be beneficial for mitigating the problem of solder flow.

Compared to conventional semiconductor devices, the usage of the additional elevated portion 6 may provide an increased metal density (in particular copper density) in the semiconductor device 200, thereby increasing heat dissipation in the semiconductor device 200. In other words, the additional metallic material of the elevated portion 6 may help to lower an operating temperature of the semiconductor device 200.

Furthermore, the upper surface 10 of the elevated portion 6 is not restricted to serve as a connection point for the electrical connection elements 18C alone. Additionally, the upper surface 10 may provide an additional area onto which additional electronic components, such as e.g. a further semiconductor chip, may be mounted. In some examples, a third semiconductor chip (not illustrated) may be mounted on the elevated portion 6. In particular, such third semiconductor chip may be a logic semiconductor chip (or driver semiconductor chip) that may be configured to control (or drive) at least one of the first semiconductor chip 16A or the second semiconductor chip 16.

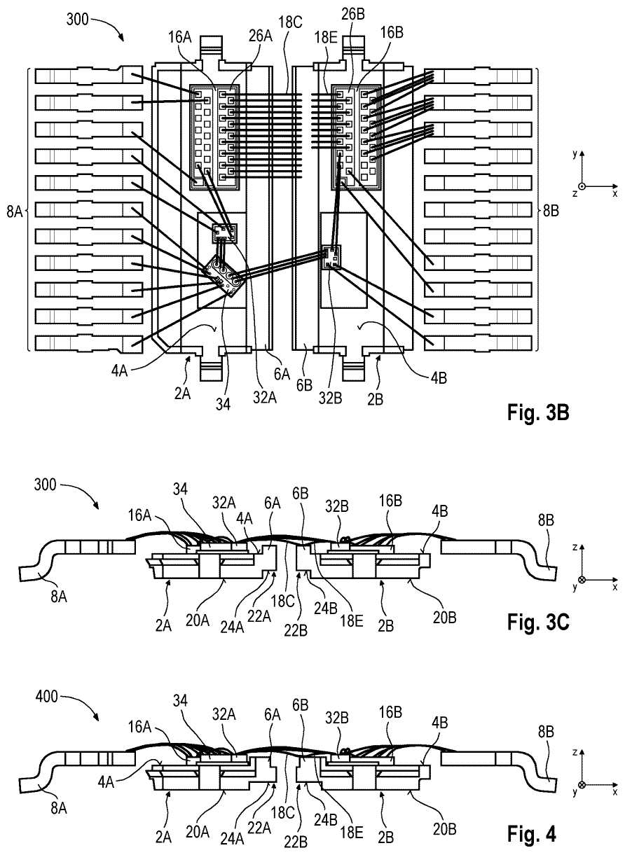

Referring now to FIG. 3A to FIG. 3C, different views of a semiconductor device 300 in accordance with the disclosure are shown. The semiconductor device 300 may include some or all features of the semiconductor device 200 of FIG. 2A and FIG. 2B. The semiconductor device 300 may include a first semiconductor chip 16A, a first driver chip 32A and a controller chip 34 mounted above the first mounting surface 4A of the first diepad 2A as well as a second semiconductor chip 16B and a second driver chip 32B mounted above the second mounting surface 4B of the second diepad 2B. Furthermore, the semiconductor device 300 may include a plurality of electrical connection elements 18 described later on. The semiconductor device 300 may include an encapsulation material similar to FIG. 2A and FIG. 2B, which is not shown in the example of FIG. 3A, FIG. 3B and FIG. 3C for illustrative purposes.

In the shown example, the second diepad 2A of the leadframe 100 may include a second elevated portion 6B elevated with respect to the second mounting surface 4B. The elevated portions 6A, 6B in FIG. 3A, FIG. 3B and FIG. 3C may be similar to elevated portions described in connection with previous examples. The first elevated portion 6A of the first diepad 2A may be arranged at a periphery of the first mounting surface 4A opposite the second diepad 2B, while the second elevated portion 6B of the second diepad 2B may be arranged at a periphery of the second mounting surface 4B opposite the first elevated portion 6A of the first diepad 2A. It is noted that a second elevated portion as shown in FIG. 3A, FIG. 3B and FIG. 3C may also be included in the examples of FIG. 1A and FIG. 1B and FIG. 2A and FIG. 2B.

As can be seen from the sectional side view of FIG. 3C, the bottom surfaces 20A, 20B of the diepads 2A, 2B may include recesses 22A, 22B opposite the first elevated portions 6A, 6B. That is, in the illustrated example, none of the bottom surfaces 20A, 20B may be flat. Similar to the previous example of FIG. 2A and FIG. 2B, the semiconductor device 300 may include an encapsulation material (not illustrated), wherein the bottom surface of the encapsulation material and the bottom surfaces 20A, 20B of the diepads 2A, 2B may be coplanar. In addition, the bottom surfaces 20A, 20B of the diepads 2A, 2B may be uncovered by the encapsulation material. Due to the recesses 22A, 22B being filled with the encapsulation material, a creepage distance between the uncovered diepads 2A, 2B along a surface of the encapsulation material may be increased compared to semiconductor devices including diepads with flat bottom surfaces.

The semiconductor chips 16A, 16B of FIG. 3A, FIG. 3B and FIG. 3C may particularly correspond to power chips and may be configured to provide similar electronic functions as described in connection with FIG. 2A and FIG. 2B. In contrast to FIG. 2A and FIG. 2B, the semiconductor chips 16A, 16B of FIG. 3A, FIG. 3B and FIG. 3C may correspond to lateral power chips. That is, while the semiconductor chips 16A, 16B may have similar or same electrical contacts as described in connection with FIG. 2A and FIG. 2B, these contacts may be arranged on the top surface of the respective semiconductor chip. The lateral power chips may be manufactured from an elemental semiconductor material (in particular silicon) or a wide band gap semiconductor material or a compound semiconductor material (in particular GaN).

In the illustrated example, the first semiconductor chip 16A may correspond to a power transistor chip, such as a power MOSFET chip or a power IGBT chip. In case of a power MOSFET, the electrical contacts arranged on the top surface of the first semiconductor chip 16A may include or correspond to a gate contact, a drain contact and a source contact of the power MOSFET. In case of a power IGBT, the discussed electrical contacts of the first semiconductor chip 16A may represent a base, a collector and an emitter of the power IGBT. The second semiconductor chip 16B may be at least partially similar to the first semiconductor chip 16A and may include similar electrical contacts arranged on its top surface as previously described.

The semiconductor chips 16A and 16B may be interconnected as follows. An electrical contact 26A arranged on the top surface of the first semiconductor chip 16A may be electrically connected to the second elevated portion 6B of the second diepad 2B via at least one electrical connection element 18C. In a similar fashion, an electrical contact 26B arranged on the top surface of the second semiconductor chip 16B may be electrically connected to the second elevated portion 6B via at least one electrical connection element 18E. In the illustrated example, the electrical connection elements 18C and 18E may include or correspond to a plurality of wires. Accordingly, the electrical contact 26A of the first semiconductor chip 16A may be electrically connected to the electrical contact 26B of the second semiconductor chip 16B via the electrical connection element 18C, the second elevated portion 6B and the second electrical connection element 18E. In case of two power MOSFET chips, a source contact of the first semiconductor chip 16A and a drain contact of the second semiconductor chip 16B may be electrically connected via the electrical connection element 18C, the second elevated portion 6B and the second electrical connection element 18E. For example, the first semiconductor chip 16A and the second semiconductor chip 16B may form part of a low side switch and a high side switch of a half bridge circuit.

The first driver chip 32A and the second driver chip 32B may include driver circuits configured to drive the first semiconductor chip 16A and the second semiconductor chip 16B, respectively. A driver circuit may be configured to drive one or more electronic components, for example a high-power transistor that may be included in the device. The driven components may be voltage driven or current driven. For example, Power MOSFETs, IGBTs, or the like, may be voltage driven switches, since their insulated gate may particularly behave like a capacitor. Conversely, switches such as triacs (triode for alternating current), thyristors, bipolar transistors, a PN diode, or the like, may be current driven. In one example, driving a component including a gate electrode may include applying different voltages to the gate electrode, e.g. in form of turn-on and turn-off switching wave forms. In a further example, a driver circuit may be used to drive a direct driven circuit.

The controller chip 34 may include a control circuit configured to control one or more of the driver chips 32A, 32B. In one example, the control circuit may simultaneously control drivers of multiple direct driven circuits. For example, a half bridge circuit including two direct driven circuits may thus be controlled by the controller chip 34. It is noted that the driver chips 32A, 32B and the controller chip 34 as shown in FIG. 3A, FIG. 3B and FIG. 3C may also be included in the semiconductor device 200 of FIG. 2A and FIG. 2B.

Referring now to FIG. 4, a sectional side view of a semiconductor device 400 in accordance with the disclosure is shown. The semiconductor device 400 may include some or all features of previously described semiconductor devices. Compared to the example of FIG. 3A, FIG. 3B and FIG. 3C, a dimension of the bottom surfaces 24A, 24B of the elevated portions 6A, 6B may be increased when measured in the x-direction. This may result in an increased creepage distance between the diepads 2A, 2B along a surface of an encapsulation material (not illustrated).

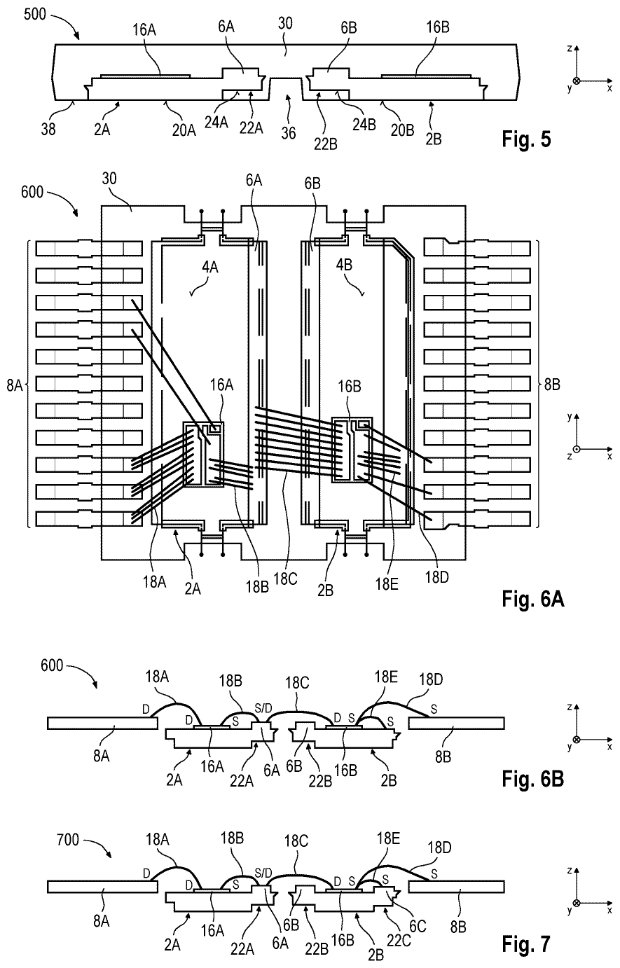

Referring now to FIG. 5, a sectional side view of a semiconductor device 500 in accordance with the disclosure is shown. The semiconductor device 500 may include some or all features of previously described semiconductor devices. In the illustrated example, multiple device components as previously described in connection with other examples are omitted for the sake of simplicity. The semiconductor device 500 may include a recess 36 formed in the main surface 38 of the encapsulation material 30. In particular, the recess 36 may be arranged between the uncovered bottom surfaces 20A, 20B of the diepads 2A, 2B and may be configured to increase a creepage distance between the uncovered bottom surfaces 20A, 20B. It is to be understood that the described feature of the recess 36 may also implemented in any other semiconductor device in accordance with the disclosure including an encapsulation material.

Referring now to FIG. 6A and FIG. 6B, different views of a semiconductor device 600 in accordance with the disclosure are shown. The semiconductor device 600 may include some or all features of previously described semiconductor device. The semiconductor device 600 may include two lateral power semiconductor chips 16A, 16B forming part of a low side switch and a high side switch of a half bridge circuit. In the illustrated example, the semiconductor chips 16A, 16B may correspond to power MOSFET chips. The sectional side view of FIG. 6B is particularly meant to illustrate source and drain connections in the semiconductor device 600.

One or more of a first plurality of leads 8A may be drain leads electrically connected to a drain contact arranged on the top surface of the first semiconductor chip 16A via a first plurality of wires 18A. A source contact arranged on the top surface of the first semiconductor chip 16A may be electrically connected to the top surface of the first elevated portion 6A of the first diepad 2A via a second plurality of wires 18B. A drain contact arranged on the top surface of the second semiconductor chip 16B may be electrically connected to the top surface of the first elevated portion 6A via a third plurality of wires 18C. Accordingly, the source contact of the first semiconductor chip 16A may be electrically connected to the drain contact of the second semiconductor chip 16B via the wires 18B, 18C and the first elevated portion 6A. Furthermore, a source contact arranged on the top surface of the second semiconductor chip 16B may be electrically connected to one or more source leads of a second plurality of leads 8B via a fourth plurality of wires 18D. In addition, the source contact of the second semiconductor chip 16B may be electrically connected to the top surface of the second diepad 2B via a fifth plurality of wires 18E.

Referring now to FIG. 7, a sectional side view of a semiconductor device 700 in accordance with the disclosure is shown. The semiconductor device 700 may be similar to the semiconductor include 600 of FIG. 6A and FIG. 6B. Compared to the example of FIG. 6A and FIG. 6B, the second diepad 2B of FIG. 7 may include an additional third elevated portion 6C and a third recess 22C formed in the bottom surface of the second diepad 2B. In the illustrated example, the fifth plurality of wires 18E may be connected to the top surface of the third elevated portion 6C. The source and drain connections in the semiconductor device 700 may be similar to FIG. 6B.

Referring now to FIG. 10, a further leadframe 1000 in accordance with the disclosure is shown. The leadframe 1000 may include some or all features of other leadframes described herein. In particular, the leadframe 1000 may be at least partially similar to the leadframe included in the semiconductor device 200 of FIG. 2A and FIG. 2B. Similar to the example of FIG. 2A and FIG. 2B, the leadframe 1000 may include power leads 8A to 8C that may be configured to be electrically connected to semiconductor chips (not illustrated) arranged on the mounting surfaces 4A, 4B of the diepads 2A, 2B. In particular, a power lead 8C may be configured to be electrically connected to a power terminal of a semiconductor chip that may be mounted on the mounting surface 4B, while a power lead 8B may be configured to be electrically connected to a power terminal of a semiconductor chip that may be mounted on the mounting surface 4A. In case of two semiconductor chips arranged on the diepads 2A, 2B and forming a half bridge circuit, the power lead 8C may correspond to a DC+ terminal, while the power lead 8B may correspond to a DC− terminal, as previously described in connection with the example of FIG. 2A and FIG. 2B. It is to be noted that the power leads 8B, 8C may be arranged at a same side of the leadframe 1000 such that a beneficial placement of one or more capacitors may be obtained in a system similar to the system 900 of FIG. 9. The power lead 8A may be configured to be electrically connected to a switch node of the half bridge circuit.

In the illustrated example, the first diepad 2A may include a first elevated portion 6A elevated with respect to the first mounting surface 4A. The first elevated portion 6A may extend along only a fraction of a side of the first mounting surface 4A. This may be in contrast to the example of FIG. 2A and FIG. 2B in which the elevated portion 6 may extend along an entire side of the mounting surface 4A. In the exemplary view of FIG. 10, the first elevated portion 6A may be arranged substantially in the middle of the left side of the first mounting surface 4A. In general, a length of the first elevated portion 6A along the side of the first mounting surface 4A may be smaller than about 50% (or about 40% or about 30% or about 20%) of the length of the side of the first mounting surface 4A.

In a similar fashion, the second diepad 2B may include a second elevated portion 6B elevated with respect to the second mounting surface 4B. The second elevated portion 6B may be arranged at a periphery of the second mounting surface 4B opposite the first elevated portion 6A of the first diepad 2A. Stated differently, the elevated portions 6A and 6B may be arranged opposite to each other or face each other. In the shown case, the second elevated portion 6B may have a shape similar to the first elevated portion 6A. In further examples, the shapes of the elevated portions 6A, 6B may differ depending on the considered application.

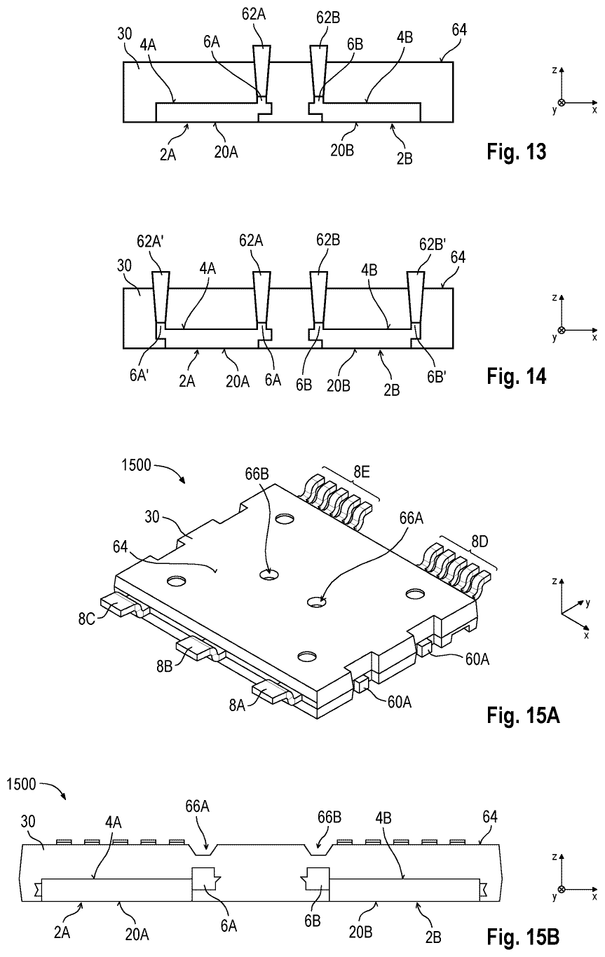

The first diepad 2A may include one or more tie bars 60A arranged at a side of the first diepad 2A opposite to the first elevated portion 6A. In the shown case, an exemplary number of two tie bars 60A is shown. In a similar fashion, the second diepad 2B may include one or more tie bars 60B arranged at a side of the second diepad 2B opposite to the second elevated portion 6B. It is to be noted that the diepads 2A, 2B do not necessarily include tie bars at the sides of the diepads where the elevated portions 6A, 6B are arranged. That is, during a molding process using a mold tool, these diepad sides without tie bars may not be mechanically fixed using tie bars, but may be floating or unadjusted, which may result in a so-called “mold flash” at the bottom surfaces of the diepads 2A, 2B. However, as will be explained later on in connection with FIG. 13 and FIG. 14, retractable pins may be used during a molding process for a mechanical fixation of the diepads in order to avoid undesired mold flashes.

FIG. 11 illustrates another example of a leadframe 1100 in accordance with the disclosure. The first diepad 2A may include a further elevated portion 6A′ elevated with respect to the first mounting surface 4A and arranged opposite to the elevated portion 6A as previously described in connection with the example of FIG. 10. In a similar fashion, the second diepad 2B may include two elevated portions 6B, 6B′ arranged at opposite sides of the second diepad 2B. In contrast to the example of FIG. 10, the diepads 2A, 2B of the leadframe 1100 do not necessarily include tie bars. This may be due to the fact that the diepads 2A, 2B may be mechanically fixed on both sides during a molding process, as described in connection with FIG. 14.

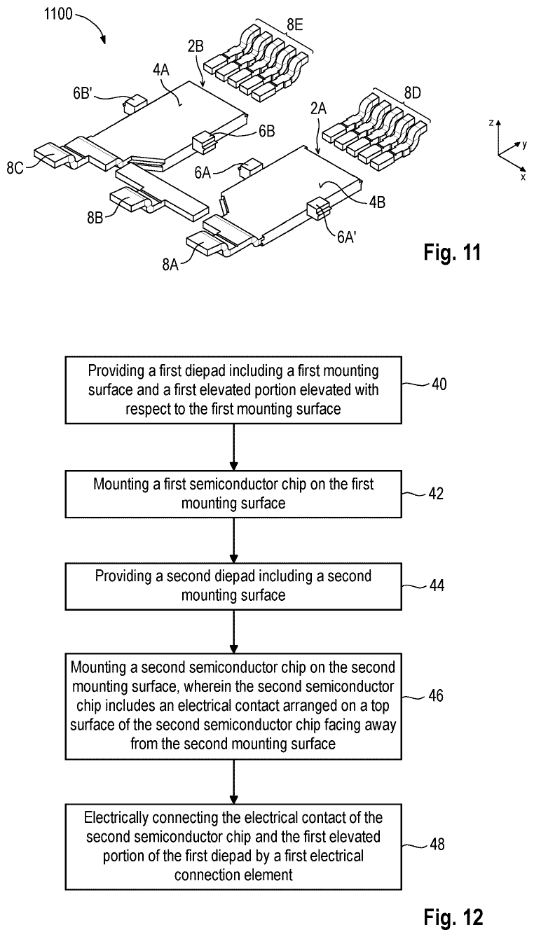

Referring now to FIG. 12, a flowchart of a method in accordance with the disclosure is illustrated. The method is described in a general manner in order to qualitatively specify aspects of the disclosure. The method may be used for manufacturing semiconductor devices in accordance with the disclosure as described herein. The method may be extended by one or more further aspects, for example any of the aspects described in connection with other example discussed herein. It is to be understood that a chronological order of the discussed method steps may be swapped or changed if technically possible and meaningful.

At 40, a first diepad including a first mounting surface and a first elevated portion elevated with respect to the first mounting surface may be provided. At 42, a first semiconductor chip may be mounted on the first mounting surface. At 44, a second diepad including a second mounting surface may be provided. At 46, a second semiconductor chip may be mounted on the second mounting surface. The second semiconductor chip may include an electrical contact arranged on a top surface of the second semiconductor chip facing away from the second mounting surface. At 48, the electrical contact of the second semiconductor chip and the first elevated portion of the first diepad may be electrically connected by a first electrical connection element.

It is to be understood that the method of FIG. 12 may include one or multiple further steps. For example, a first power lead may be electrically connected to a power terminal of the first semiconductor chip, and a second power lead may be electrically connected to a power terminal of the second semiconductor chip. Here, the first power lead and the second power lead may be arranged at a same side of the semiconductor device. Referring back to the example of FIG. 2A, the power leads 8B, 8C may be electrically connected to the semiconductor chips 16A, 16B as previously described.

Further optional steps of a method for manufacturing a semiconductor device in accordance with the disclosure are now described in connection with FIG. 13. In the illustrated example, diepads 2A, 2B may be arranged in an encapsulation tool or mold tool (not illustrated). For example, the diepads 2A, 2B may be part of a leadframe similar to the leadframe 1000 of FIG. 10. It is to be noted that semiconductor chips may be arranged on the mounting surfaces 4A, 4B of the diepads 2A, 2B, which may be interconnected as described in previous examples. However, for the sake of simplicity, such semiconductor chips and associated electrical interconnections are not illustrated in FIG. 13.

The first diepad 2A may be pressed against a surface of the encapsulation tool by means of a first retractable pin 62A. In the illustrated example, the first diepad 2A may be pushed downwards such that the bottom surface 20A of the first diepad 2A may be pressed against the surface of the encapsulation tool, thereby mechanically fixing the first diepad 2A. More particular, the first retractable pin 62A may be pressed against the first elevated portion 6A of the first diepad 2A. In a similar fashion, the second diepad 2B may be pressed against a surface of the encapsulation tool by means of a second retractable pin 62B. Here, the second retractable pin 62B may be pressed against the second elevated portion 6B of the second diepad 2B.

In a next step, the diepads 2A, 2B and the retractable pins 62A, 62B may be encapsulated by arranging an encapsulation material 30 in the encapsulation tool. For example, a molding material may be injected into the volume of a mold tool containing the diepads 2A, 2B. Since the diepads 2A, 2B may be firmly pressed against an inner wall of the encapsulation tool by means of the retractable pins 62A, 62B, no encapsulation material can reach the space between the bottom surfaces 20A, 20B of the diepads 2A, 2B and the tool. In case of a molding process, undesired mold flashes may therefore be avoided.

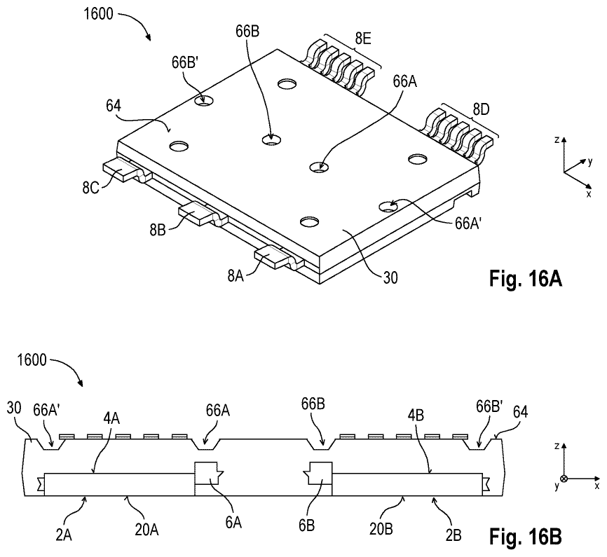

After embedding the arrangement into the encapsulation material 30, the retractable pins 62A, 62B may be removed (in particular pulled back), wherein recesses may be formed in the main surface 64 of the encapsulation material 30. A first recess may be arranged above the first diepad 2A, while a second recess may be arranged above the second diepad 2B. More particular, the first recess and the first elevated portion 6A may at least partially overlap in a top view of the first diepad 2A (i.e. when viewed in the z-direction). In a similar fashion, the second recess and the second elevated portion 6B may at least partially overlap in a top view of the second diepad 2B. Exemplary semiconductor devices in accordance with the disclosure including recesses formed in an encapsulation material are discussed in connection with FIG. 15A and FIG. 15B and FIG. 16A and FIG. 16B.

FIG. 14 illustrates other exemplary steps of a method for manufacturing a semiconductor device in accordance with the disclosure. The method steps may be at least partially similar to the method steps of FIG. 13. In the shown case, the diepads 2A, 2B may be part of a leadframe similar to the leadframe 1100 of FIG. 11. That is, each of the diepads 2A, 2B may include two elevated portions arranged at opposite sides of the respective diepad. The first diepad 2A may be mechanically fixed similar to FIG. 13 by pressing the retractable pin 62A against the first elevated portion 6A, but now an additional retractable pin 62A′ may be pressed against the further elevated portion 6A′ of the first diepad 2A arranged on the opposite side of the first diepad 2A. In a similar fashion, the second diepad 2B may be mechanically fixed by means of two retractable pins 62B, 62B′ pressed against the two elevated portions 62B, 62B′ of the second diepad 2B.

Referring now to FIG. 15A and FIG. 15B, a perspective bottom view and a sectional side view of a semiconductor device 1500 in accordance with the disclosure are shown. For example, the semiconductor device 1500 may include a leadframe similar to the leadframe 1000 of FIG. 10. In the shown case, the diepads 2A, 2B of the leadframe and the semiconductor chips (not illustrated) arranged thereon may have been encapsulated in an encapsulation material 30 by using retractable pins as previously described in connection with FIG. 13. Accordingly, a first recess 66A may be formed in the main surface 64 of the encapsulation material 30, wherein the first recess 66A may be arranged above the first diepad 2A. More particular, the first recess 66A and the first elevated portion 6A may at least partially overlap in a top view of the first diepad 2A (i.e. when viewed in the z-direction). In a similar fashion, a second recess 66B may be formed in the main surface 64 of the encapsulation material 30 above the second diepad 2B. In some non-limiting examples, each of the recesses 66A, 66B may have a depth in a range from about 0.5 μm to about 3 μm.

Referring now to FIG. 16A and FIG. 16B, a perspective bottom view and a sectional side view of a semiconductor device 1600 in accordance with the disclosure are shown. For example, the semiconductor device 1600 may include a leadframe similar to the leadframe 1100 of FIG. 11. Since two retractable pins may have been pressed against the elevated portions 6A, 6A′ of the first diepad 2A, the main surface 64 of the encapsulation material 30 may include two recesses 66A, 66A′ arranged above the elevated portions 6A, 6A′, respectively. In a similar fashion, two further recesses 66B, 66B′ may be formed in the main surface 64 of the encapsulation material 30 above the two elevated portions 6B, 6B′ of the second diepad 2B.

### EXAMPLES

In the following, semiconductor devices, leadframes, systems and associated manufacturing methods in accordance with the disclosure are described by means of examples.

Example 1 is a semiconductor device, comprising: a first diepad comprising a first mounting surface and a first elevated portion elevated with respect to the first mounting surface; a first semiconductor chip mounted on the first mounting surface; a second diepad comprising a second mounting surface; a second semiconductor chip mounted on the second mounting surface and comprising an electrical contact arranged on a top surface of the second semiconductor chip facing away from the second mounting surface; and a first electrical connection element electrically connecting the electrical contact of the second semiconductor chip and the first elevated portion of the first diepad.

Example 2 is the semiconductor device of Example 1, further comprising: a first power lead electrically connected to a power terminal of the first semiconductor chip; and a second power lead electrically connected to a power terminal of the second semiconductor chip, wherein the first power lead and the second power lead are arranged at a same first side of semiconductor device.

Example 3 is the semiconductor device of Example 2, wherein the first power lead and the second power lead are arranged directly next to each other.

Example 4 is the semiconductor device of Example 2 or 3, wherein one of the first power lead and the second power lead is configured to receive a supply power and/or a supply voltage, and the other one of the first power lead and the second power lead is configured to output an electric current.

Example 5 is the semiconductor device of any of Examples 2 to 4, further comprising: a third power lead electrically connected to the first semiconductor chip and the second semiconductor chip, wherein the third power lead is arranged at the first side of the semiconductor device next to the first power lead and the second power lead.

Example 6 is the semiconductor device of Example 5, wherein the third power lead is configured to output a power and/or a signal.

Example 7 is the semiconductor device of any of the preceding Examples, wherein the first semiconductor chip and the second semiconductor chip form part of a low side switch and a high side switch of a half bridge circuit.

Example 8 is the semiconductor device of Example 2 and Example 7, wherein: the first power lead is electrically connected to the low side switch, and the second power lead is electrically connected to the high side switch.

Example 9 is the semiconductor device of Example 2 and any of Examples 7 to 8, wherein each of the first power lead and the second power lead is a DC terminal of the half bridge circuit.

Example 10 is the semiconductor device of Example 5 and any of Examples 7 to 9, wherein the third power lead is electrically connected to a switch node of the half bridge circuit.

Example 11 is the semiconductor device of any of the preceding Examples, wherein: power terminals of the first semiconductor chip and of the second semiconductor chip are exclusively electrically connected to leads arranged at one side of the semiconductor device, and logical terminals of the first semiconductor chip and of the second semiconductor chip are exclusively electrically connected to leads arranged at an opposite side of the semiconductor device.

Example 12 is the semiconductor device of any of the preceding Examples, further comprising: an encapsulation material at least partially encapsulating the first diepad, the second diepad, the first semiconductor chip and the second semiconductor chip; and a recess formed in a surface of the encapsulation material, wherein the recess is arranged above the first diepad.

Example 13 is the semiconductor device of Example 12, wherein the recess and the first elevated portion at least partially overlap in a top view of the first diepad.

Example 14 is the semiconductor device of any of the preceding Examples, wherein the first elevated portion extends along an entire side of the first mounting surface.

Example 15 is the semiconductor device of any of Examples 1 to 13, wherein the first elevated portion extends along a fraction of a side of the first mounting surface, wherein a length of the first elevated portion along the side of the mounting surface is smaller than 50% of the length of the side of the mounting surface.

Example 16 is the semiconductor device of any of the preceding Examples, wherein: the first diepad comprises a further elevated portion elevated with respect to the first mounting surface, and the first elevated portion is arranged at a first side of the first mounting surface, and the further elevated portion is arranged at a second side of the first mounting surface opposite to the first side.

Example 17 is the semiconductor device of any of the preceding Examples, further comprising: a third semiconductor chip mounted on the first elevated portion.

Example 18 is the semiconductor device of Example 17, wherein the third semiconductor chip is a logic semiconductor chip configured to control at least one of the first semiconductor chip or the second semiconductor chip.

Example 19 is the semiconductor device of any of the preceding Examples, wherein each of the first semiconductor chip and the second semiconductor chip is based on silicon carbide.

Example 20 is the semiconductor device of any of the preceding Examples, wherein a bottom surface of the first diepad opposite the first mounting surface and a bottom surface of the first elevated portion are coplanar.

Example 21 is the semiconductor device of any of the preceding Examples, wherein: the second diepad comprises a second elevated portion elevated with respect to the second mounting surface, and the second elevated portion is arranged at a periphery of the second mounting surface opposite the first elevated portion of the first diepad.

Example 22 is a method for manufacturing a semiconductor device, the method comprising: providing a first diepad comprising a first mounting surface and a first elevated portion elevated with respect to the first mounting surface; mounting a first semiconductor chip on the first mounting surface; providing a second diepad comprising a second mounting surface; mounting a second semiconductor chip on the second mounting surface, wherein the second semiconductor chip comprises an electrical contact arranged on a top surface of the second semiconductor chip facing away from the second mounting surface; and electrically connecting the electrical contact of the second semiconductor chip and the first elevated portion of the first diepad by a first electrical connection element.

Example 23 is the method of Example 22, further comprising: electrically connecting a first power lead to a power terminal of the first semiconductor chip; and electrically connecting a second power lead to a power terminal of the second semiconductor chip, wherein the first power lead and the second power lead are arranged at a same side of the semiconductor device.

Example 24 is the method of Example 22 or 23, further comprising: arranging the first diepad and the second diepad in an encapsulation tool; pressing the first diepad against a surface of the encapsulation tool by means of a retractable pin; encapsulating the first diepad, the second diepad and the retractable pin by arranging an encapsulation material in the encapsulation tool; and removing the retractable pin, wherein a recess is formed in a surface of the encapsulation material, wherein the recess is arranged above the first diepad.

Example 25 is the method of Example 24, wherein: the retractable pin is pressed against the first elevated portion, and the recess and the first elevated portion at least partially overlap in a top view of the first diepad.

Example 26 is a leadframe, comprising: a first diepad comprising a first mounting surface and a first elevated portion elevated with respect to the first mounting surface; and a second diepad comprising a second mounting surface, wherein the first elevated portion is arranged at a periphery of the first mounting surface opposite the second diepad.

Example 27 is the leadframe of Example 26, further comprising: a first power lead configured to be electrically connected to a power terminal of a first semiconductor chip mounted on the first mounting surface; and a second power lead configured to be electrically connected to a power terminal of a second semiconductor chip mounted on the second mounting surface, wherein the first power lead and the second power lead are arranged at a same side of the leadframe.

Example 28 is the leadframe of Example 26 or 27, wherein: the second diepad comprises a second elevated portion elevated with respect to the second mounting surface, and the second elevated portion is arranged at a periphery of the second mounting surface opposite the first elevated portion of the first diepad.

Example 29 is the leadframe of any of Examples 26 to 28, wherein the first diepad further comprises one or more tie bars arranged at a side of the first diepad opposite to the first elevated portion.

Example 30 is a system, comprising: a semiconductor device of any of Examples 2 to 21; a printed circuit board, wherein the semiconductor device is arranged on the printed circuit board, wherein the first power lead is electrically connected to a first conductive trace of the printed circuit board, wherein the second power lead is electrically connected to a second conductive trace of the printed circuit board; and at least one capacitor electrically connected between the first conductive trace and the second conductive trace.

As employed in this description, the terms “connected”, “coupled”, “electrically connected”, and/or “electrically coupled” may not necessarily mean that elements must be directly connected or coupled together. Intervening elements may be provided between the “connected”, “coupled”, “electrically connected”, or “electrically coupled” elements.

Further, the words “over”, “on”, or the like, used with regard to e.g. a material layer formed or located “over” or “on” a surface of an object may be used herein to mean that the material layer may be located (e.g. formed, deposited, etc.) “directly on”, e.g. in direct contact with, the implied surface. The words “over” and “on” used with regard to e.g. a material layer formed or located “over” or “on” a surface may also be used herein to mean that the material layer may be located (e.g. formed, deposited, etc.) “indirectly on” the implied surface with e.g. one or more additional layers being arranged between the implied surface and the material layer.

Furthermore, to the extent that the terms “having”, “containing”, “including”, “with”, or variants thereof are used in either the detailed description or the claims, such terms are intended to be inclusive in a manner similar to the term “comprising”. That is, as used herein, the terms “having”, “containing”, “including”, “with”, “comprising”, and the like are open-ended terms that indicate the presence of stated elements or features, but do not preclude additional elements or features. The articles “a”, “an”, and “the” are intended to include the plural as well as the singular, unless the context clearly indicates otherwise.

Moreover, the word “exemplary” is used herein to mean serving as an example, instance, or illustration. Any aspect or design described herein as “exemplary” is not necessarily to be construed as advantageous over other aspects or designs. Rather, use of the word exemplary is intended to present concepts in a concrete fashion. As used in this application, the term “or” is intended to mean an inclusive “or” rather than an exclusive “or”. That is, unless specified otherwise, or clear from context, “X employs A or B” is intended to mean any of the natural inclusive permutations. That is, if X employs A; X employs B; or X employs both A and B, then “X employs A or B” is satisfied under any of the previous instances. In addition, the articles “a” and “an” as used in this application and the appended claims may generally be construed to mean “one or more” unless specified otherwise or clear from context to be directed to a singular form. Also, at least one of A and B or the like generally means A or B or both A and B.

Devices and methods for manufacturing devices are described herein. Comments made in connection with a described device may also hold true for a corresponding method and vice versa. For example, if a specific component of a device is described, a corresponding method for manufacturing the device may include a step of providing the component in a suitable manner, even if such step is not explicitly described or illustrated in the figures.

Although the disclosure has been shown and described with respect to one or more implementations, equivalent alterations and modifications will occur to others skilled in the art based at least in part upon a reading and understanding of this description and the annexed drawings. The disclosure includes all such modifications and alterations and is limited only by the concept of the following claims. In particular regard to the various functions performed by the above described components (e.g., elements, resources, etc.), the terms used to describe such components are intended to correspond, unless otherwise indicated, to any component which performs the specified function of the described component (e.g., that is functionally equivalent), even though not structurally equivalent to the disclosed structure which performs the function in the herein illustrated exemplary implementations of the disclosure. In addition, while a particular feature of the disclosure may have been disclosed with respect to only one of several implementations, such feature may be combined with one or more other features of the other implementations as may be desired and advantageous for any given or particular application.

1. A semiconductor device, comprising:
a first diepad comprising a first mounting surface and a first elevated portion elevated with respect to the first mounting surface;
a first semiconductor chip mounted on the first mounting surface;
a second diepad comprising a second mounting surface;
a second semiconductor chip mounted on the second mounting surface and comprising an electrical contact arranged on a top surface of the second semiconductor chip facing away from the second mounting surface; and
a first electrical connection element electrically connecting the electrical contact of the second semiconductor chip and the first elevated portion of the first diepad.

2. The semiconductor device of claim 1, further comprising:
a first power lead electrically connected to a power terminal of the first semiconductor chip; and
a second power lead electrically connected to a power terminal of the second semiconductor chip,
wherein the first power lead and the second power lead are arranged at a same first side of semiconductor device.

3. The semiconductor device of claim 2, wherein the first power lead and the second power lead are arranged directly next to each other.

4. The semiconductor device of claim 2, wherein one of the first power lead and the second power lead is configured to receive a supply power and/or a supply voltage, and the other one of the first power lead and the second power lead is configured to output an electric current.

5. The semiconductor device of claim 2, further comprising:
a third power lead electrically connected to the first semiconductor chip and the second semiconductor chip, wherein the third power lead is arranged at the first side of the semiconductor device next to the first power lead and the second power lead.

6. The semiconductor device of claim 5, wherein the third power lead is configured to output a power and/or a signal.

7. The semiconductor device of claim 1, wherein the first semiconductor chip and the second semiconductor chip form part of a low side switch and a high side switch of a half bridge circuit.

8. The semiconductor device of claim 2, wherein:
the first power lead is electrically connected to the low side switch, and
the second power lead is electrically connected to the high side switch.

9. The semiconductor device of claim 2, wherein each of the first power lead and the second power lead is a DC terminal of the half bridge circuit.

10. The semiconductor device of claim 5, wherein the third power lead is electrically connected to a switch node of the half bridge circuit.

11. The semiconductor device of claim 1, wherein:
power terminals of the first semiconductor chip and of the second semiconductor chip are exclusively electrically connected to leads arranged at one side of the semiconductor device, and
logical terminals of the first semiconductor chip and of the second semiconductor chip are exclusively electrically connected to leads arranged at an opposite side of the semiconductor device.

12. The semiconductor device of claim 1, further comprising:
an encapsulation material at least partially encapsulating the first diepad, the second diepad, the first semiconductor chip and the second semiconductor chip; and
a recess formed in a surface of the encapsulation material, wherein the recess is arranged above the first diepad.

13. The semiconductor device of claim 12, wherein the recess and the first elevated portion at least partially overlap in a top view of the first diepad.

14. The semiconductor device of claim 1, wherein the first elevated portion extends along an entire side of the first mounting surface.

15. The semiconductor device of claim 1, wherein the first elevated portion extends along a fraction of a side of the first mounting surface, wherein a length of the first elevated portion along the side of the mounting surface is smaller than 50% of the length of the side of the mounting surface.

16. The semiconductor device of claim 1, wherein:
the first diepad comprises a further elevated portion elevated with respect to the first mounting surface, and
the first elevated portion is arranged at a first side of the first mounting surface, and
the further elevated portion is arranged at a second side of the first mounting surface opposite to the first side.

17. The semiconductor device of claim 1, further comprising:
a third semiconductor chip mounted on the first elevated portion.

18. The semiconductor device of claim 17, wherein the third semiconductor chip is a logic semiconductor chip configured to control at least one of the first semiconductor chip or the second semiconductor chip.

19. The semiconductor device of claim 1, wherein each of the first semiconductor chip and the second semiconductor chip is based on silicon carbide.

20. The semiconductor device of claim 1, wherein a bottom surface of the first diepad opposite the first mounting surface and a bottom surface of the first elevated portion are coplanar.

21. The semiconductor device of claim 1, wherein:
the second diepad comprises a second elevated portion elevated with respect to the second mounting surface, and
the second elevated portion is arranged at a periphery of the second mounting surface opposite the first elevated portion of the first diepad.

22. A method for manufacturing a semiconductor device, the method comprising:
providing a first diepad comprising a first mounting surface and a first elevated portion elevated with respect to the first mounting surface;
mounting a first semiconductor chip on the first mounting surface;
providing a second diepad comprising a second mounting surface;
mounting a second semiconductor chip on the second mounting surface, wherein the second semiconductor chip comprises an electrical contact arranged on a top surface of the second semiconductor chip facing away from the second mounting surface; and
electrically connecting the electrical contact of the second semiconductor chip and the first elevated portion of the first diepad by a first electrical connection element.

23. The method of claim 22, further comprising:
electrically connecting a first power lead to a power terminal of the first semiconductor chip; and
electrically connecting a second power lead to a power terminal of the second semiconductor chip,
wherein the first power lead and the second power lead are arranged at a same side of the semiconductor device.

24. The method of claim 22, further comprising:
arranging the first diepad and the second diepad in an encapsulation tool;
pressing the first diepad against a surface of the encapsulation tool by means of a retractable pin;
encapsulating the first diepad, the second diepad and the retractable pin by arranging an encapsulation material in the encapsulation tool; and
removing the retractable pin, wherein a recess is formed in a surface of the encapsulation material, wherein the recess is arranged above the first diepad.

25. The method of claim 24, wherein:
the retractable pin is pressed against the first elevated portion, and
the recess and the first elevated portion at least partially overlap in a top view of the first diepad.

26. A leadframe, comprising:
a first diepad comprising a first mounting surface and a first elevated portion elevated with respect to the first mounting surface; and
a second diepad comprising a second mounting surface,
wherein the first elevated portion is arranged at a periphery of the first mounting surface opposite the second diepad.

27. The leadframe of claim 26, further comprising:
a first power lead configured to be electrically connected to a power terminal of a first semiconductor chip mounted on the first mounting surface; and
a second power lead configured to be electrically connected to a power terminal of a second semiconductor chip mounted on the second mounting surface,
wherein the first power lead and the second power lead are arranged at a same side of the leadframe.

28. The leadframe of claim 26, wherein:
the second diepad comprises a second elevated portion elevated with respect to the second mounting surface, and
the second elevated portion is arranged at a periphery of the second mounting surface opposite the first elevated portion of the first diepad.

29. The leadframe of claim 26, wherein the first diepad further comprises one or more tie bars arranged at a side of the first diepad opposite to the first elevated portion.

30. A system, comprising:
a semiconductor device of claim 2;
a printed circuit board, wherein the semiconductor device is arranged on the printed circuit board,
wherein the first power lead is electrically connected to a first conductive trace of the printed circuit board,
wherein the second power lead is electrically connected to a second conductive trace of the printed circuit board; and
at least one capacitor electrically connected between the first conductive trace and the second conductive trace.
